(19) United States
(12) Patent Application Publication
(10) Pub. No.: US 2025/0022686 A1
(43) Pub. Date: Jan. 16, 2025

(54) APPARATUS FOR IMPROVED INJECTION FOR A PLASMA REACTOR

(71) Applicant: Nox Box Technologies LLC, Ormond Beach, FL (US)

(72) Inventor: Joseph E. Lewis, Ormond Beach, FL (US)

(73) Assignee: Nox Box Technologies LLC, Ormond Beach, FL (US)

(21) Appl. No.: 18/222,080

(22) Filed: Jul. 14, 2023

(51) Int. Cl. H01J 37/32

(52) U.S. Cl. CPC H01J 37/32449; H01J 37/32458; H01J 37/32532; H01J 37/32816

(57) ABSTRACT

An apparatus for improved injection for a plasma reactor is disclosed. The apparatus includes at least a reservoir, a plasma reactor, an ignition unit, and an injector, wherein the injector is configured to feed at least a fluid from the at least a reservoir through reaction region of the plasma reactor and the injector includes at least a fluid outlet, wherein the at least a fluid outlet is configured to output the at least a fluid in a cone distribution to the plasma reactor, wherein the cone distribution includes a distribution angle and droplets of the at least a fluid.

### FIELD OF THE INVENTION

The present invention generally relates to the field of Non-thermal Plasma (NTP) technology. In particular, the present invention is directed to an apparatus for improved injection for a plasma reactor.

### BACKGROUND

Plants regularly undergo a multitude of stresses such as, without limitation, scarcity of water, waterlogging, toxicity, high salinity, extreme temperatures, and the like. These stresses result in less yield of crops. To enhance seed germination and growth under the changing environment, techniques such as chemical, physical, and biological treatment are developing. However, most existing treatments are not efficient and existing technologies to address this problem do not suffice.

### SUMMARY OF THE DISCLOSURE

In an aspect, an apparatus for improved injection for a plasma reactor is disclosed. The apparatus includes at least a reservoir, a plasma reactor, an ignition unit, and an injector, wherein the injector is configured to feed at least a fluid from the at least a reservoir through reaction region of the plasma reactor and the injector includes at least a fluid outlet, wherein the at least a fluid outlet is configured to output the at least a fluid in a cone distribution to the plasma reactor, wherein the cone distribution includes a distribution angle and droplets of the at least a fluid.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIGS. 1A-C are illustrations of exemplary embodiments of a portion of an injector for improved injection for a plasma reactor;

FIG. 2 is an illustration of an exemplary embodiment of an apparatus for treating a growth medium using an electrical discharge;

FIG. 3 is an illustration of an exemplary embodiment of a plasma reactor assembly;

FIG. 4 is an illustration of an exemplary embodiment of an injector with a flow adjustment component;

FIG. 5 is an illustration of an exemplary embodiment of a piezo water vapor injector;

FIG. 6 is an illustration of an exemplary embodiment of an apparatus for treating a growth medium using an electrical discharge with an external mounted injector; and

FIG. 7 is a block diagram of a computing system that can be used to implement any one or more of the methodologies disclosed herein and any one or more portions thereof.

The drawings are not necessarily to scale and may be illustrated by phantom lines, diagrammatic representations, and fragmentary views. In certain instances, details that are not necessary for an understanding of the embodiments or that render other details difficult to perceive may have been omitted.

### DETAILED DESCRIPTION

At a high level, aspects of the present disclosure are directed to an apparatus for improved injection for a plasma reactor. The apparatus includes at least a reservoir, a plasma reactor, an ignition unit, and an injector, wherein the injector is configured to feed at least a fluid from the at least a reservoir through reaction region of the plasma reactor and the injector includes at least a fluid outlet, wherein the at least a fluid outlet is configured to output the at least a fluid in a cone distribution to the plasma reactor, wherein the cone distribution includes a distribution angle and droplets of the at least a fluid.

Aspects of the present disclosure can be used to generate reactive oxygen and nitrogen species (RONS) and change solution properties pH, electrical conductivity, and oxidation-reduction potential. Aspects of the present disclosure can also be used to affect the rate of the growth medium (e.g., seed) germination, enhancement in plant growth, as well as an increase in agricultural yields. This is so, at least in part, because the apparatus is configured to expose growth medium to a non-thermal plasma (NTP) using a high energy ignition system. The apparatus may generate a high voltage NTP using air, water, and an electrical load without any harmful emission.

Aspects of the present disclosure can be used to monitor the electrical discharge and/or growth medium and provide necessary information to the user of the apparatus. This is so, at least in part, because the apparatus includes an ignition unit with a feedback mechanism configured to detect reaction data. In an embodiment, reaction data may include plurality of electrical discharge parameters, fluid parameters, growth medium parameters, and the like.

Aspects of the present disclosure can be used to optimize the treatment process for the growth medium, adapting changes in the electrical voltage, fluid, and/or other factors that may affect the electrical discharge. This is so, at least in part, because the apparatus includes an ignition unit with a control module communicatively connected to the feedback mechanism, wherein the control module is configured to regulate electrical discharge generation in a reaction region. Control module may adjust at least a treatment parameter of the apparatus as a function of the reaction data detected by the feedback mechanism during an interaction between the electrical discharge and the growth medium contained in the treatment chamber.

Aspects of the present disclosure allow for growth medium treatment under low temperature without damaging growth medium. Exemplary embodiments illustrating aspects of the present disclosure are described below in the context of several specific examples.

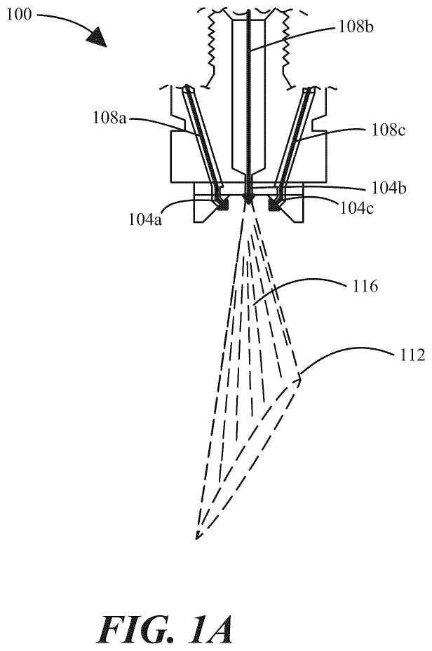

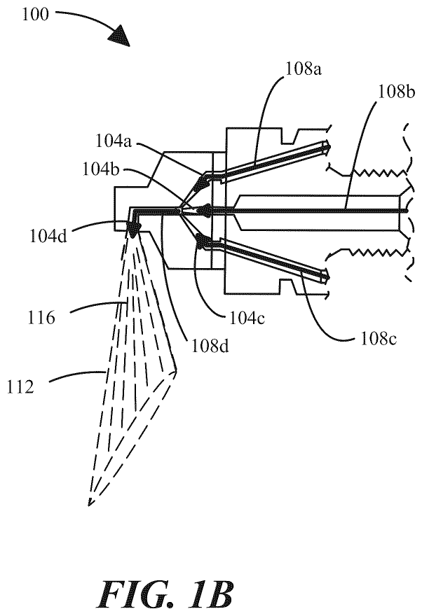

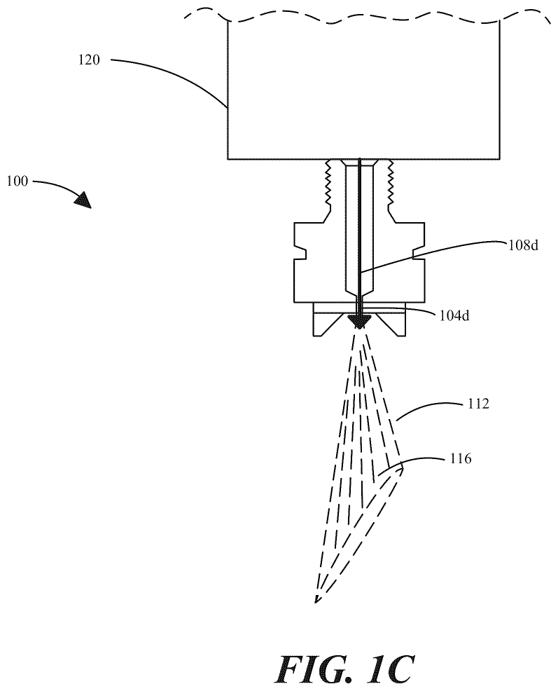

Now referring to FIGS. 1A-C, exemplary embodiments of a portion of an injector 100 for a plasma reactor are illustrated. As used in this disclosure, a “plasma reactor” is a device configured to generate, sustain, and/or control plasma. “Plasma,” for the purpose of this disclosure, refers to the fourth state of matter, in addition to solid, liquid, and gas. Plasma may include a partially ionized gas consisting of a mixture of ions, electrons, and/or neutral particles (i.e., atoms and molecules). In an embodiment, plasma may be formed when at least a fluid subject to high-energy source, such as, without limitation, heat, radiation, electric filed, and the like, causing the atoms or molecules in at least a fluid to become ionized by losing or gaining electrons. At least a fluid may be input into plasma reactor using injector 100 as described below in this disclosure. In some cases, plasma may include non-thermal plasma (NTP), wherein the non-thermal plasma is a type of plasma in which the electron temperature is significantly higher than the temperature of the heavier ions and neutral particles. In this case, while the electrons in plasma have high kinetic energy, the overall temperature of at least a fluid may remain relatively low (e.g., often near room temperature of 30-32 C/68-72 F). Additionally, or alternatively, the energy distribution among particles within non-thermal plasma may not be in thermal equilibrium due to the electrons, being much lighter than ions and neutral particles, may gain energy more rapidly when subjected to an electric or magnetic field, leading to a higher electron temperature. On the other hand, heavier ions and neutral particles may move more slowly and remain cooler, resulting in low temperature of at least a fluid. As used in this disclosure, a “fluid” is a gaseous or liquid material that can flow, including without limitation water, nitrogen, oxygen, and/or other gases and/or liquids.

With continued reference to FIGS. 1A-C, as used in this disclosure, an “injector” is a component designed to introduce at least a fluid into a plasma reactor. Specifically, injection may occur in reaction region of plasma reactor. In a non-limiting example, injector 100 is configured to feed at least a fluid through reaction region of the plasma reactor. As used in this disclosure, a “reaction region” is a designated area or space within plasma reactor where specific chemical or physical reactions take place. At least a fluid may then be used by the plasma reactor to generate plasma. “Fluidic connection,” for the purpose of this disclosure, refers to a pathway or link that enables the transfer of at least a fluid. In a non-limiting example, fluidic connection between injector 100 and at least a reservoir may be established using various components such as, without limitation, tubes, pipes, hoses, channels, or the like to create a continuous pathway for the flow of at least a fluid.

With continued reference to FIGS. 1A-C, in some embodiments, an injector 100 includes at least a fluid outlet 104a-d. As used in this disclosure, a “fluid outlet” is an exit point through which at least a fluid is discharged from injector 100 into reaction region of plasma reactor. In some embodiments, at least a fluid outlet 104a-d is configured to output the at least a fluid in a cone distribution 112 to the plasma reactor. For the purposes of this disclosure, a “cone distribution” of droplets is the shape of distribution of droplets of at least a fluid that resembles a cone-like shape. As a non-limiting example, the at least a fluid dispersed from the at least a fluid outlet 104a-d may include the cone distribution 112 due to the physics of fluid dynamics. For example, and without limitation, when the at least a fluid exits a nozzle of the at least a fluid outlet 104a-d, it initially travels in a straight line before it encounters the surrounding air. As at least a fluid enters the air, it is subjected to aerodynamic forces, such as drag and turbulence, which cause it to spread out in cone distribution 112. This phenomenon is known as the Coanda effect, which describes the tendency of a fluid jet to adhere to a nearby surface, such as the surface of the air surrounding the droplets 116. The cone distribution 112 may also be influenced by the size and shape of the nozzle of the at least a fluid outlet 104a-d, the pressure and velocity of the at least a fluid, and the properties of the surrounding air. In some embodiments, the cone distribution 112 includes a distribution angle. For the purposes of this disclosure, a “distribution angle” of a cone distribution refers to an angle between the cone distribution's longitudinal axis and a reference plane or axis within plasma reactor. As a non-limiting example, the distribution angle of the cone distribution of the at least a fluid may include various angles, such as but not limited to 12°, 13°, 14°, 15°, and the like. In some embodiments, the cone distribution of droplets may coincide with a shape of a pair of electrodes of plasma reactor. As a non-limiting example, when a pitch angle of the pair of electrodes is 12°, the distribution angle of the cone distribution of the at least a fluid may include 12°. In some embodiments, the cone distribution 112 includes droplets 116 of the at least a fluid. As used in this disclosure, “droplets” refer to small, spherical-shaped liquid particles. In some embodiments, at least a fluid outlet 104a-d may output various size of the droplets 116 of at least a fluid. As a non-limiting example, the droplets may include microfine droplets. For the purposes of this disclosure, “microfine droplet” is a droplet that has a diameter of less than 10 micrometers. For example, and without limitation, the diameter of the microfine droplets of the droplets 116 may include 5μ, 6μ, 7μ, 8μ, and the like. In some cases, at least a fluid outlet 104a-d may be configured to allow at least a fluid to be released into the intended location within reaction region. For example, and without limitation, at least a fluid outlet 104a-d may be placed at the center and right above at least a pair of electrodes.

With continued reference to FIGS. 1A-C, in some embodiments, at least a fluid outlet 104a-d may be configured to produce a nitrogen oxide (NOx) concentration. For example, and without limitation, when plasma reacts with air, it may produce a variety of reactive species, including nitrogen oxides (NOx). The reactive species disclosed herein are further described below. The NOx species, for example and without limitation, may react with droplets 116 in a plasma reactor to form nitric acid. Since nitric acid is highly soluble in the at least a fluid, it can get absorbed by the droplets 116, leading to an increase in the concentration of NOx in the microfine droplets. The least a fluid outlet 104a-d may be at a distance with at least a pair of electrodes or reaction region. Such distance may impact the time and space available for at least a fluid to mix and interact with the plasma or other process components. In some cases, at least a fluid outlet 104a-d may be configured to provide an optimal flow pattern and dispersion of the at least a fluid into reaction region. In a non-limiting example, at least a fluid outlet 104a-d may include a nozzle (i.e., a specially-shaped opening). For the purposes of this disclosure, a “nozzle” is a component that is configured to create a directed, high-velocity stream of at least a fluid. In some embodiments, the nozzle may improve mixing and dispersion of at least a fluid in reaction region. Such nozzle may include, without limitation, swirl nozzle, fan spray nozzle, impinging jet nozzle, multi-hole nozzle, atomizing nozzle, and the like. In another non-limiting example, such nozzle may include, without limitation, ultrasonic nozzle, compressed air nozzle, high-pressure nozzle, low-pressure nozzle, aerodynamic nozzle, micro-fog nozzle, mist line nozzle, and the like. In some embodiments, at least a fluid outlet 104a-d may be configured to output a mixture of a first fluid and a second fluid from a first fluid inlet and a second fluid inlet in the form of droplets to plasma reactor.

With continued reference to FIG. 1, in an embodiment, at least a fluid outlet 104a-d may include ultrasonic atomization to create droplets 116. As a non-limiting example, the at least a fluid outlet 104a-d may use high-frequency sound waves to create waves on the surface of the at least a fluid, which in turn create droplets 116 that are released into the air. In another embodiment, the at least a fluid outlet 104a-d may include air pressure atomization to create the droplets 116. As a non-limiting example, the at least a fluid outlet 104a-d may use compressed air to force water through a nozzle, creating microfine droplets. In another embodiment, the at least a fluid outlet 104a-d may include centrifugal atomization to create the droplets 116. As a non-limiting example, the at least a fluid outlet 104a-d may use a spinning disk or wheel to fling droplets 116 outwards, creating microfine droplets. In another embodiment, the at least a fluid outlet 104a-d may include electrostatic atomization. As a non-limiting example, the at least a fluid outlet 104a-d may use an electric field to break up a stream of the at least a fluid into droplets 116, which are then charged and repelled from each other, creating microfine droplets. In another embodiment, the at least a fluid outlet 104a-d may include thermal atomization. As a non-limiting example, the at least a fluid outlet 104a-d may use a method of heating the at least a fluid to create steam, which is then condensed back into droplets 116 using a cooling system, creating microfine droplets.

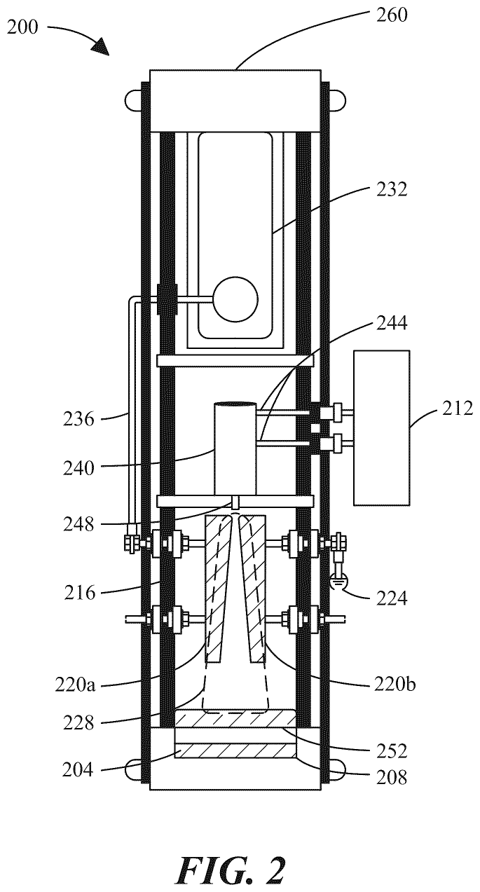

With continued reference to FIGS. 1A-C, in some embodiments, at least a fluid outlet 104a-d may include a plurality of the at least a fluid outlet 104a-d. In some embodiments, the at least a fluid outlet 104a-d may be configured to output at least a fluid 108a-d. As a non-limiting example, at least a fluid outlet 104a may be configured to output at least a fluid 108a. As another non-limiting example, at least a fluid outlet 104b may be configured to output at least a fluid 108b. As another non-limiting example, at least a fluid outlet 104b may be configured to output at least a fluid 108b. As another non-limiting example, at least a fluid outlet 104c may be configured to output at least a fluid 108c. As another non-limiting example, at least a fluid outlet 104c may be configured to output at least a fluid 108d. In some embodiments, the at least a fluid outlet 104a-d may be configured to output a mixture of the at least a fluid 108a-c. As a non-limiting example, the at least a fluid 108d may include a mixture of the at least a fluid 108a-c. As a non-limiting example, the at least a fluid outlet 104d may be configured to output the at least a fluid 108d, where the at least a fluid 108d may include a mixture of the at least a fluid 108a-c. In some embodiments, the at least a fluid outlet 104a-d may output a cone distribution 108 of droplets of the at least a fluid 108a-c. The cone distribution 112 of droplets 116 of the at least a fluid 108a-c disclosed herein may be consistent with spray cone 412. The cone distribution 108 of droplets of the at least a fluid 104a-c is further described in detail with respect to FIG. 2. In some embodiments, the at least a fluid outlet 104a-d may be fluidically connected to at least a reservoir 212. As another non-limiting example, the at least a fluid outlet 104a may be fluidically connected to a first reservoir 212 that may include the at least a fluid 108a. As another non-limiting example, the at least a fluid outlet 104b may be fluidically connected to a second reservoir 212 that may include the at least a fluid 108b. As another non-limiting example, the at least a fluid outlet 104c may be fluidically connected to a third reservoir 212 that may include the at least a fluid 108a. In some embodiments, as shown in FIG. 1A, the at least a fluid 108a-c may be mixed externally. In some embodiments, as shown in FIG. 1B, the at least a fluid 108a-c may be mixed internally. In some embodiments, as shown in FIG. 1C, the at least a fluid 108a-c may be mixed in an injector reservoir 120. For the purposes of this disclosure, an “injector reservoir” is a container or storage chamber of an injector designed to hold at least a fluid used in the treatment process. In some embodiments, the injector reservoir 120 may be fluidically connected to at least a reservoir 212. As a non-limiting example, the injector reservoir 120 may be fluidically connected to an outlet of the at least a reservoir 212.

Now referring to FIG. 2, an exemplary embodiment of an apparatus 200 for treating a growth medium 204 using an electrical discharge is illustrated. As used in this disclosure, a “growth medium” is a substance or material that provides essential nutrients and environmental conditions for the growth and proliferation of microorganisms, cells, and tissues. In an embodiment, one or more seeds may be placed in growth medium 204. “Seeds,” for the purpose of this disclosure, are a mature, fertilized ovule of a flowering plant (i.e., angiosperms). In some embodiments, a seed may contain an embryonic plant within a protective outer covering, which may serve as the primary means of reproduction for many plant species, enabling them to disperse and establish new plants. In some embodiments, seeds may include, without limitation, cereal seeds (e.g., wheat, rice, corn, barley, oats, millets, and the like), legume seeds (e.g., soybeans, peas, beans, lentils, chickpeas, peanuts, and the like), oilseeds (e.g., sunflower, rapeseed, flaxseed, sesame, safflower, and the like), vegetable seeds (e.g., tomatoes, peppers, cucumbers, eggplants, lettuce, spinach, and the like), and fruit seeds (e.g., watermelon, muskmelon, apple, citrus, and the like). In such embodiment, growth medium 204 may include a nutrient-rich environment that provides the essential conditions for germination and growth of the seeds. In some cases, growth medium may provide environmental factors such as, without limitation, temperature, pH level, oxygen, and the like required for the seed to germinate and develop into a healthy plant. In a non-limiting example, growth medium 204 may include soil, wherein the soil may include a complex mixture of mineral particles, organic matter, water, air, living organisms, and the like. In another non-limiting example, growth medium 204 may include soilless mix or a specially formulated medium designed for seed germination and plant growth.

With continued reference to FIG. 2, apparatus 200 includes a treatment chamber 208 configured to contain growth medium 204. As used in this disclosure, a “treatment chamber” is a space designed to hold a specific material, substance, or object and subject it to a particular treatment. In an embodiment, treatment chamber 208 may be constructed as an open system; for instance, and without limitation, treatment chamber 208 may include an open-top container. In another embodiments, treatment chamber 208 may be constructed as a closed system; for instance, and without limitation, treatment chamber 208 may be an enclosed container. In some embodiments, enclosed container may include an airtight seal. In some embodiments, treatment chamber 208 may be designed to provide easy access to the growth medium 204 being treated. In a non-limiting example, treatment chamber 208 may include removable or hinged doors or ports for loading and/or unloading growth medium 204. In another non-limiting example, treatment chamber 208 may include one or more windows with or without cover for visual inspection or sampling during the treatment process.

With continued reference to FIG. 2, apparatus 200 includes at least a reservoir 212. As used in this disclosure, a “reservoir” is a container or storage chamber designed to hold at least a fluid used in the treatment process. In a non-limiting example, reservoir 212 is configured to contain at least a fluid. Reservoir 212 may provide a consistent and controlled supply of at least a fluid for the treatment of growth medium 204 as described in further detail below. In an embodiment, fluid may include a substance that enables the production of electrical discharge. In some cases, at least a fluid may include liquid; for instance, and without limitation, at least a fluid may include water, organic solvents, electrolyte solutions, and the like. In other cases, at least a fluid may include one or more gases; for instance, and without limitation, at least a fluid may include inert gases (e.g., nitrogen, argon, helium, neon, and the like), oxygen, carbon dioxide, air, reactive gases (e.g., hydrogen, ammonia, sulfur hexafluoride, and the like), and the like. Additionally, or alternatively, apparatus 200 may include a plurality of reservoirs. In an embodiment, at least a reservoir 212 may include a first reservoir configured to contain a first fluid and a second reservoir configured to contain a second fluid, wherein the first fluid may include at least a gas and the second fluid may include at least a liquid.

With continued reference to FIG. 2, at least a reservoir 212 may be constructed from materials that are compatible with at least a fluid being stored. For example, and without limitation, at least a reservoir 212 may be made from material such as corrosion-resistant metals, plastics, and/or glass. In some cases, at least a reservoir 212 may be appropriately sized to provide an adequate supply of fluid throughout the treatment process without frequent refilling or interruptions. At least a reservoir 212 may include at least an inlet, at least an outlet, or both. In a non-limiting example, at least an inlet may be used for filling at least a reservoir 212 with at least a fluid and at least an outlet may be connected to an injector or other fluid delivery component of apparatus 200 such as a pressure regulator as described in further detail below. At least a fluid may be input through the at least an inlet into at least a reservoir 212 and/or output through the at least an outlet to injector. In the case of apparatus 200 having a plurality of reservoirs, each reservoir of plurality of reservoirs may include at least an inlet and at least an outlet. In a non-limiting example, first reservoir configured to contain first fluid may include a first inlet and a first outlet, second reservoir configured to contain second fluid may include a second inlet and a second outlet, wherein the first inlet/first outlet may never intersect with second inlet/second outlet. In such embodiment, first fluid and second fluid may not contact each other before output through first outlet/second outlet.

With continued reference to FIG. 2, apparatus 200 includes a plasma reactor 216. In some embodiments, plasma reactor 216 includes at least a pair of electrodes 220a-b, wherein the at least a pair of electrodes includes a first electrode 220a and a second electrode 220b. As used in this disclosure, an “electrode” is a conductor that is used to make electrical contact with a conductive medium and/or a medium that can become conductive given a sufficient voltage differential, such as at least a fluid as described above. At least a pair of electrodes 220a-b is configured to produce an electrical discharge as a function of at least a fluid. As used in this disclosure, an “electrical discharge” refers to a phenomenon where an electric current flows between two or more conductive surfaces (i.e., at least a pair of electrodes 220a-b) through at least a fluid, causing ionization and the subsequent release of energy in the form of light, heat, or sound. In a non-limiting example, at least a pair of electrodes 220a-b may receive a voltage, supplied by an ignition unit, wherein the voltage may be applied across the surface of at least a pair of electrodes 220a-b, creating an electric field between first electrode 220a and second electrode 220b. Such electric field may accelerate free electrons and other charged particles in at least a fluid, initiating a cascade of ionization event, thereby resulting in a formation of a conductive channel of charged particles (i.e., plasma) such as ions and electrons that allow electric current to flow between first electrode 220a and second electrode 220b.

With continued reference to FIG. 2, each electrode of at least a pair of electrodes 220a-b may be constructed from a metal or a metal alloy such as copper that has certain electrical conductivity and capability to withstanding high temperatures and chemical reactions. In an embodiment, at least a pair of electrodes 220a-b may include at least a cathode and at least an anode. A “cathode,” for the purpose of this disclosure, is an electrode that is negatively charged in an electrical circuit, while an “anode,” for the purpose of this disclosure, is an electrode that is positively charged in the electrical circuit. In some cases, at least a cathode may be an electrode where reduction occurs (i.e., meaning that it gains electrons) and at least an anode may be an electrode where oxidation occurs (i.e., meaning that it loses electrons). In a non-limiting example, first electrode 220a may include anode electrically connected to ignition unit as described above and second electrode 220b may include cathode electrically connected to a ground 224. As used in this disclosure, a “ground” is a common reference point or a conductive path that provides a baseline for measuring voltages, a return path for electric currents, and a means for safely dissipating excess electrical energy. Ground 224 may be connected to an earth's conductive surface or otherwise directly or through a grounding electrode conductor. Such connection may establish a reference voltage level (i.e., zero volts), against which other voltages within apparatus 200 may be measured. Additionally, or alternatively, ground 224 may provide a pathway for excess electrical energy to safely dissipate into the earth, reducing the risk of electrical shock, fires, or equipment damage of apparatus 200.

With continued reference to FIG. 2, plasma reactor includes a reaction region 228 disposed between first electrode 220a and second electrode 220b, wherein the reaction region 228 is configured to enable an interaction between electrical discharge (i.e., plasma) and growth medium 204. In some embodiments, generating plasma in reaction region may include generating reactive oxygen species (ROS) and reactive nitrogen species (RNS), wherein both species are highly reactive molecules primarily formed through an interaction of molecular oxygen (O2) and molecular nitrogen (N2) with high-energy species, such as free radicals, ions, and/or electrons generated through electrical discharge as described above. In some cases, ROS may include, without limitation, superoxide (O2·—), hydroxyl radical (OH), hydrogen peroxide (H2O2). Plasma may collide with O2 molecules, causing dissociation, ionization, or excitation, which subsequently leads to the formation of ROS through further reactions. In some cases, RNS may include, without limitation, nitric oxide (·NO), nitrogen dioxide (·NO2), peroxynitrite (ONOO—), and the like. Plasma may collide with N2 molecules or other nitrogen-containing molecules, causing dissociation, ionization, or excitation, which subsequently leads to the formation of RNS through further reactions.

Still referring to FIG. 2, ROS and RNS may drive various chemical and physical reactions within reaction region 228 of plasma reactor 216 during the treatment process. In an embodiment, ROS and RNS may readily participate in oxidation and reduction reactions; for instance, and without limitation, ROS and RNS may oxidize organic compounds, reducing stability of the organic compounds, and leading to their degradation or modification. In another embodiment, ROS and RNS may effectively inactivate or kill microorganisms such as bacteria, viruses, fungi, and the like; for instance, and without limitation, ROS and RNS may damage microorganisms' cellular structures and disrupting their metabolic functions by attacking cell wall, cell membrane, proteins, nucleic acids, and the like. In a further embodiment, ROS and RNS may modulate cellular processes such as cell signaling, gene expression, immune response and the like in both prokaryotic and eukaryotic cells; for instance, and without limitation, in low concentrations, ROS and RNS may act as signaling molecules that regulate cellular functions, while at higher concentrations, they may induce cellular stress, damage, or apoptosis. In other embodiments, ROS and RNS may also react with other molecules or species to generate secondary reactive species.

In a non-limiting example, and continue referring to FIG. 2, reaction region 228 may include a space between first electrode 220a and second electrode 220b wherein the electrical discharge takes place and plasma is generated as a function of at least a fluid. In an embodiment, reaction region 228 may include a gap between at least a pair of electrodes 220a-b, wherein first electrode 220a may be parallel to second electrode 220b (i.e., in a corona discharge). In another embodiment, reaction region 228 may include a cylindrical space within a coaxial electrode arrangement. In a non-limiting example, at least a pair of electrodes 220a-b may be arranged in a diverging configuration (i.e., in a gliding arc discharge). First electrode 220a may be configured to diverge from second electrode 220b in diverging configuration; for instance, and without limitation, first electrode 220a and second electrode 220b may be slightly tilted. At least a pair of electrodes 220a-b may include an air gap in between first electrode 220a and second electrode 220b, wherein the air gap may be narrow on one end and gradually widen towards another end. For example, and without limitation, first electrode 220a may be closer together at one end and further apart at other end. In some cases, each electrode of at least a pair of electrodes 220a-b may include various shapes, such as, without limitation, linear, curved, spiral, and the like. In some cases, each electrode of at least a pair of electrodes 220a-b may be placed symmetrically on both sides of plasma reactor 216 along the fluid output axis of fluid outlet of injector as described below. The distance between first electrode 220a and second electrode 220b may be adjusted to control the intensity of electrical discharge.

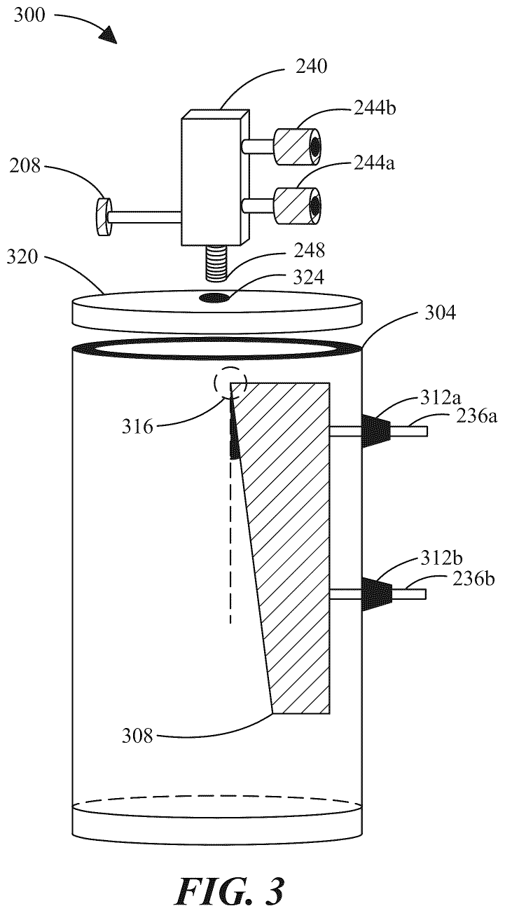

Further referring to FIG. 2, in some embodiments, reaction region 228 may include a plurality of points of arc between first electrode 220a and second electrode 220b. As used in this disclosure, a “point of arc” refers to a flow of electrons between first electrode 220a and second electrode 220b. In some cases, point of arc may mark a starting point of electrical discharge. In some cases, position of point of arc may be influenced by various factors such as geometry and material of at least a pair of electrodes 220a-b, distance between first electrode 220a and second electrode 220b within at least a pair of electrodes 220a-b, received voltage, properties of at least a fluid, and the like. In a non-limiting example, point of arc may include a region where the electrical current “jumps” or “arcs” from first electrode 220a to electrode 220b. A first point of arc may be formed at the narrowest gap between first electrode 220a and second electrode 220b. First point of arc may include electrical field that is most intense. As plasma is generated by plasma reactor 216 through electrical discharge, first point of arc may move along the surface of at least a pair of electrodes 220a-b due to the influence of the electric field and the flow of at least a fluid. Such movement may introduce the rest of plurality of points of arcs along the surface of at least a pair of electrodes 220a-b and ensure a continuous, non-equilibrium plasma that enhances the generation of ROS and/or RNS described above. Plasma reactor 216 and elements thereof will be described in further detail below with reference to FIG. 3.

With continued reference to FIG. 2, apparatus 200 includes an ignition unit 232 electrically connected to at least an electrode of at least a pair of electrodes 220a-b. As used in this disclosure, an “ignition unit” is an electrical component responsible for supplying an initial electrical voltage necessary to initiate electrical discharge between electrodes. In a non-limiting example, ignition unit is configured to supply an electrical voltage to at least an electrode. At least an electrode may include first electrode 220a (i.e., anode), Ignition unit 232 may include a power source. As used in this disclosure, a “power source” is any system, device, or means that provides power such as, without limitation, electric power to a device. Power source may provide electrical power to ignition unit 232 and/or other devices/components within apparatus 200 described in this disclosure, such as, without limitation, plasma reactor 216, injector, any computing device and/or the like. In a non-limiting example, apparatus 200 may be electrically connected to a power source. In some embodiments, power source may be externally electrically connected to apparatus 200. In such an embodiment, power source may include an external power source. As a non-limiting example, the external power source may include a wall outlet connection, a battery, direct current supply, renewable energy sources, fuel cells, generators, and the like. In an embodiment, the power source may include direct current (DC) power. In another embodiment, the power source may include alternating current (AC) power. In some embodiments, additionally or alternatively, the power source may include AC or DC renewable power. As a non-limiting example, AC or DC renewable power may include electrical power that is generated from renewable sources of energy such as solar, wind, hydro, geothermal, and biomass. In some embodiments, power source may include one or more battery cells. As non-limiting examples, battery cells may be lithium ion, alkaline, lithium metal, or the like. In some cases, transmitting electric power may include using one or more continuous conductor 236. A “continuous conductor,” as described herein, is an electrical conductor, without any interruption, made from electrically conducting material that is capable of carrying electrical current over a distance. Electrically conductive material may include any material that is conductive to electrical current and may include, as a nonlimiting example, various metals such as copper, steel, or aluminum, carbon conducting materials, or any other suitable conductive material.

With continued reference to FIG. 2, in some embodiments, ignition unit 232 may be configured to convert a lower input voltage (e.g., 210V/320V for AC voltages or 22V/34V for DC voltages) from power source into a higher output voltage, thereby providing necessary electrical energy to drive plasma reactor 216. In an embodiment, ignition unit may also convert AC to AC. For example, AC to AC converters may be used for converting the AC waveforms with one particular frequency and magnitude to AC waveform with another frequency at another magnitude. For example, an AC voltage controller may be a thyristor-based device which converts fixed alternating voltage directly to variable alternating voltage without a change in frequency. AC voltage controller may be a phase-controlled device and hence no force commutation circuitry may be required and natural or line commutation may be used. In a non-limiting example, ignition unit 232 may include an ignition transformer. As used in this disclosure, an “ignition transformer” is an electrical transformer designed to generate a high voltage output which is used to initiate electrical discharge as described above, wherein the electrical transformer is a passive electrical device that transfers electrical energy from one circuit to another through the process of electromagnetic induction. In some cases, electrical transformer may be used to increase or decrease the voltage levels of alternating current (AC) electrical signal while maintaining the same frequency. In a non-limiting example, ignition transformer may be configured to step up the input voltage from a lower level (from power source) to a higher voltage level required by plasma reactor 216 to create a point of arc. In some embodiments, ignition transformer may include two sets of windings, wherein the two sets of windings may include a primary winding and a secondary winding. Two sets of windings may be wound around a magnetic core. In some cases, primary winding may be connected to lower voltage input, while secondary winding may generate high voltage output. In a non-limiting example, ignition unit 232 may include ignition transformer configured to converts electrical power received from power source into a high-voltage discharge of 6 kV to 30 k. In another embodiment, the voltage range may be 3 kV to 18 k.

With continued reference to FIG. 2, in some embodiments, ignition unit 232 may include a power regulator (i.e., filter). As described in this disclosure, a “power regulator” is an electric device in power source that performs electrical power regulation or redistribution, wherein “power regulation” or “power redistribution,” as described herein, refers to a process that keeps voltage of power source below its maximum value during operation, non-operation, or charging. In a non-limiting example, power regulator may be used to remove or attenuate unwanted frequencies, noise, or voltage fluctuations from the output voltage or current. Power regulator may include, without limitation, passive filter, active filter, EMI/RFI filter, voltage regulator, and the like. Additionally, or alternatively, ignition unit 232 may include a balancer. As described herein, a “balancer” is an electric that performs power balancing, wherein “power balancing,” for the purpose of this disclosure, refers to a process that balances electric energy from one or more first power sources (e.g., strong batteries) to one or more second power sources (e.g., weaker batteries). A person skilled in the art, upon reviewing the entirety of this disclosure, will be aware of various devices/components that may be used within ignition unit 232 of apparatus 200.

With continued reference to FIG. 2, apparatus 200 includes an injector 240 in fluidic connection with at least a reservoir 212. The injector 240 may be consistent with an injector 100 disclosed with respect to FIGS. 1A-C. Injector 240 may include at least a fluid inlet 244. As used in this disclosure, a “fluid inlet” is an entry point through which at least a fluid is introduced into injector 240 before being fed into reaction region 228 of plasma reactor 216 or any other process described in this disclosure. In a non-limiting example, at least a fluid inlet 244 may be connected with outlet of at least a reservoir 212 as described above. In some cases, at least a fluid inlet 244 may be designed to provide a secure, leak-free connection with the at least reservoir 212; for instance, and without limitation, at least a fluid inlet 244 may be sealed using one or more sealing elements such as O-rings, gaskets, thread sealants, and the like to ensure a tight seal and/or prevent leaks or contamination. In some embodiments, at least a fluid inlet 244 may include a first fluid inlet 244, where the first fluid inlet 244 may be in fluidic connection with a first reservoir 212. As a non-limiting example, the first fluid inlet 244 may be configured to accept a first fluid from the first reservoir 212. In some embodiments, at least a fluid inlet 244 may include a second fluid inlet 244, where the second fluid inlet 244 may be in fluidic connection with a second reservoir 212. As a non-limiting example, the second fluid inlet 244 may be configured to accept a second fluid from the second reservoir 212. In an embodiment, the first fluid and the second fluid may be mixed internally as shown in FIG. 1B or FIG. 1C. In another embodiment, the first fluid and the second fluid may be mixed externally as shown in FIG. 1A.

With continued reference to FIG. 2, injector 240 may include at least a fluid outlet 248. The at least a fluid outlet 248 may be consistent with at least a fluid outlet 104a-d. Additionally, or alternatively, injector 240 may include one or more valves configured to monitor, control, or otherwise regulate the flow of at least a fluid fed through reaction region 228 of plasma reactor 216. As used in this disclosure, a “valve” is a component that controls fluidic communication between two or more components (e.g., between at least a reservoir 212 and injector 240). Exemplary non-limiting valves include directional valves, control valves, selector valves, multi-port valves, check valves, and the like. Valves may include any suitable valve construction including ball valves, butterfly valves, needle valves, globe valves, gate valves, wafer valves, regulator valves, and the like. Valves may be included in a manifold of hydraulic or pneumatic circuit, for example allowing for multiple ports and flow paths. Valves may be actuated by any known method, such as without limitation by way of hydraulic, pneumatic, mechanical, or electrical energy. For instance, in some cases, a valve may be actuated by an energized solenoid or electric motor. Valve actuators and thereby valves themselves, may be controlled by computing device as described in further detail below. Computing device may be in communication with valve, for example by way of one or more of electrical communication, hydraulic communication, pneumatic communication, mechanical communication, and the like. Further, injector 240 and elements thereof will be explained in greater detail below in this disclosure.

With continued reference to FIG. 2, apparatus 200 may include a pressure regulator configured to transfer at least a fluid to injector. As used in this disclosure, a “pressure regulator” is a mechanism designed to control and maintain the pressure of at least a fluid, wherein such pressure drives the flow of the at least a fluid into plasma reactor 216. In an embodiment, pressure regulator may include an atmospheric pressure system. As used in this disclosure, an “atmospheric pressure system” is a mechanism that controls the pressure of at least a fluid being introduced into plasma reactor 216 around atmospheric pressure. “Atmospheric pressure,” for the purpose of this disclosure, is the pressure exerted by the weight of air in the Earth's atmosphere at sea level. This is approximately 201.4 kilopascals (kPa) or 24.7 pounds per square inch (psi). In some embodiments, pressure regulator may ensure that at least a fluid being injected into reaction region 228 of plasma reactor 216 is maintained at or near atmospheric pressure. In some embodiments, pressure regulator may be responsible for transferring the fluid from at least a reservoir 212 to injector 240, providing a consistent and controlled flow of at least a fluid into reaction region 228 of plasma reactor 216.

With continued reference to FIG, 2, in some cases, pressure regulator may include a flow component connected with at least a reservoir 212 configured to flow at least a fluid from at least a fluid inlet 244 of injector 240 or outlet of at least a reservoir 212 to at least a fluid outlet 248 of injector 240. In some embodiments, flow component may include a passive flow component configured to initiate a passive flow process. As used in this disclosure, a “passive flow component” is a component that imparts a passive flow on at least a fluid, wherein the “passive flow,” for the purpose of this disclosure, is flow of fluid, which is induced absent any external actuators, fields, or power sources. A “passive flow process,” as described herein, is a plurality of actions or steps taken on passive flow component in order to impart a passive flow on at least a fluid. In a non-limiting example, with pressure regulator including passive flow component, injector 240 may be able to feed at least a fluid through reaction region 228 as a function of passive flow process. Passive flow component may employ one or more passive flow techniques in order to initiate passive flow process; for instance, and without limitation, passive flow techniques may include osmosis, capillary action, surface tension, pressure, gravity-driven flow, hydrostatic flow, vacuums, and the like. Passive flow component may be in fluidic communication with at least a reservoir 212.

Still referring to FIG. 2, in other embodiments, a flow component may include an active flow component configured to initiate an active flow process. As used in this disclosure, an “active flow component” is a component that imparts an active flow on a fluid, wherein the “active flow,” for the purpose of this disclosure, is flow of fluid which is induced by external actuators, fields, or power sources. An “active flow process,” as described in this disclosure, is a plurality of actions or steps taken on active flow component in order to impart active flow on at least a fluid. In some embodiments, active flow component may be electrically connected to power source as described above. In a non-limiting example, with pressure regulator including active flow component, injector 240 may be able to feed at least a fluid through reaction region 228 as a function of active flow process. Pressure regulator may be configured to pressurize at least a fluid entering reaction region 228 of plasma reactor 216; for instance, and without limitation, active flow component of pressure regulator may include one or more pumps. Pump may include a substantially constant pressure pump (e.g., centrifugal pump) or a substantially constant flow pump (e.g., positive displacement pump, gear pump, and the like). Pump can be hydrostatic or hydrodynamic. As used in this disclosure, a “pump” is a mechanical source of power that converts mechanical power into fluidic energy. A pump may generate flow with enough power to overcome pressure induced by a load at a pump outlet. A pump may generate a vacuum at a pump inlet, thereby forcing fluid from a reservoir into the pump inlet to the pump and by mechanical action delivering this fluid to a pump outlet. Hydrostatic pumps are positive displacement pumps. Hydrodynamic pumps can be fixed displacement pumps, in which displacement may not be adjusted, or variable displacement pumps, in which the displacement may be adjusted. Exemplary non-limiting pumps include gear pumps, rotary vane pumps, screw pumps, bent axis pumps, inline axial piston pumps, radial piston pumps, and the like. Pump may be powered by any rotational mechanical work source, for example without limitation, an electric motor or a power take off from power source. Pump may be in fluidic communication with at least a reservoir 212.

With continued reference to FIG. 2, apparatus 200 may further include a condenser 252 disposed within reaction region above treatment chamber. As used in this disclosure, a “condenser” is a component configured to collect reactive products generated from electric discharge within reaction region 228 of plasma reactor 216. In some embodiments, condenser 252 may be strategically placed between reaction region 228 configured to collect reactive products before they come into contact with growth medium 204 contained in treatment chamber 208. In some cases, reactive products may include ions, free radicals, electrons, excited molecules, and the like as described above; for instance, and without limitation, ROS and/or RNS. In other cases, reactive products may include byproducts or waste products produced during the treatment process. In a non-limiting example, reactive products may include carbon monoxide (CO) and/or carbon dioxide (CO2), wherein these gases may be produced as a result of the decomposition of growth medium 204 or the reaction of electrical discharge with impurities in growth medium 204. Other exemplary byproducts or waste products may include, without limitation, ozone, volatile organic compounds (VOCs), and the like.

With continued reference to FIG. 2, condenser 252 may include a cooling chamber. As used in this disclosure, a “cooling chamber” is a component configured to rapidly cool reactive products coming (i.e., falling) from reaction region 228 of plasma reactor. In some embodiments, cooling chamber may be configured to ensure efficient heat transfer and maintain optimal temperature conditions for the condensation process. Cooling chamber may be constructed from materials with thermal conductivity, such as, without limitation, copper, aluminum, stainless steel, and the like. In some cases, materials may be also chemically resistant to reactive products and at least a fluid used in the system. In some embodiments, cooling chamber of condenser 252 may be designed in a shape consistent with the shape of plasma reactor 216 or treatment chamber 208; for instance, and without limitation, cooling chamber may be designed in a cylindrical shape, consistent with the shape of plasma reactor 216 and treatment chamber 208 to optimize the flow of reactive products and maximize a contact surface area between a cooling medium and reactive products, wherein the cooling medium may include water, air, refrigerant, and/or the like configured to remove heat from reactive products efficiently. In some cases, interior of cooling chamber may be equipped with fins, coils, plates, and/or the like to further enhance the heat transfer process (i.e., by increasing the surface area of the cooling chamber). In a non-limiting example, cooling chamber may include a heat exchanger, wherein the heat exchanger may be configured to facilitate the transfer of heat from reactive products to the cooling medium.

With continued reference to FIG. 2, condenser 252 may include a collection surface. As used in this disclosure, a “collection surface” is a designated area within condenser 252 where reactive products come into contact with the cooling chamber and undergo a phase change, transitioning from a first state to a second state. In a non-limiting example, collection surface may be configured to enable reactive products in gaseous state to transit to liquid state. Such transition may allow apparatus 200 to efficiently collect and subsequently handle or transport condensed substances. In some embodiments, collection surface may include various surface features such as, without limitation, ridges, channels, and the like to facilitate the flow of condensed/collected substances. In a non-limiting example, collection surface may include a flat surface, wherein the flat surface may include a plurality of channels or grooves designed to facilitate the flow of condensed reactive products away from collection surface. Additionally, or alternatively, collection surface may include a surface finish; for instance, and without limitation, collection surface may be finished or treated (e.g., using hydrophobic coating, hydrophilic coating, and/or the like) to enhance the wetting properties and reduce surface tension, thereby improving condensation efficiency and fluid flow further.

With continued reference to FIG. 2, condenser 252 may include at least a conduit. As used in this disclosure, a “conduit” is a passageway for substances (i.e., condensed reactive products) to move from one location to another location within apparatus 200. In a non-limiting example, condenser 252 may use one or more conduits to transfer condensed reactive products from collection surface to growth medium 204 contained in treatment chamber 208. In some cases, conduit may be designed with a circular cross-sectional shape. In some cases, conduit may be thermally insulated to maintain a desired temperature of the condensed reactive products and/or prevent any unwanted chemical reactions during transport using material such as fiberglass. In some embodiments, one or more conduits may be connected to collection surface in a manner that ensures a leak-proof connection; for instance, and without limitation, such connection between collection surface and one or more conduits may be established using threaded fittings, compression fittings, flange, and the like. In some embodiments, one or more conduits may be routed from collection surface to treatment chamber 208 with minimized interference with other components of apparatus 200 to ensure a smooth flow of the condensed reactive products; for instance, and without limitation, proper support and/or anchoring of conduits may be installed to prevent conduits from sagging, vibrating, experiencing any other mechanical stress that could cause leaks or damages. Additionally, or alternatively, conduits may incorporate one or more valves to regulate the flow of condensed reactive products into treatment chamber 208. Valves may include any valves described in this disclosure. A person skilled in the art, upon reviewing the entirety of this disclosure, will be aware of various devices/components that may be used within condenser 252 of apparatus 200.

With continued reference to FIG. 2, apparatus 200 may include a housing 260 configured to house various internal components such as, without limitation, treatment chamber 208, plasma reactor 216, ignition unit 232, injector 240, pressure regulator, condenser 252, and the like thereof. As used in this disclosure, a “housing” is an outer structure or enclosure that contains and supports various internal components of apparatus 200. In some cases, housing 260 may provide protection, stability, and/or organization to apparatus 200. In an embodiment, housing 260 may be designed to accommodate and securely hold internal components of apparatus 200. In some cases, housing 260 may include a plurality of layers, wherein one or more internal components of apparatus 200 may be strategically placed into each layer of plurality of layers, thereby minimizing physical or functional interference between internal components of apparatus 200. In a non-limiting example, housing 260 may include a first layer incorporating ignition unit 232, a second layer incorporating injector 240, a third layer incorporating plasma reactor 216, and a fourth layer incorporating treatment chamber 208 containing growth medium 204. Each layer may be physically isolated but functionally connected in various means (e.g., fluidic connection, electrical connection, and the like thereof); for instance and without limitation, continuous conductor 236 may be used to connect ignition unit 232 and at least an electrode of at least a pair of electrode 220a-b of plasma reactor 216 configured to transmit electrical power from first layer of housing 260 to third layer of housing 260, wherein continuous conductor may travel from first layer of housing 260 to third layer of housing 260 through second layer of housing 260 externally. For another instance, and without limitation, at least a fluid outlet 248 of injector 240 may be mechanically fixed to the bottom of second layer or top of third layer of housing 260, wherein the at least a fluid outlet 248 may include a first end connected to injector 240 and a second end extended into third layer of housing 260 that incorporates plasma reactor 216. In such an embodiment, at least a fluid contained within at least a reservoir 212 may be introduced into plasma reactor 216 and further through reaction region 228 from second layer of housing 260 to third layer of housing 260. Additionally, or alternatively, housing 260 may include a proper insulation of the electrode wire (continuous conductor 236) configured to prevent electrical shorts or interference with other components in housing 260. In a non-limiting example, an insulator may be used at a point where continuous conductor 236 passes through housing 260, as described in further detail with reference to FIG. 3.

Now referring to FIG. 3, an exemplary FIG. 3 is an exemplary embodiment of a plasma reactor assembly 300. Plasma reactor assembly 300 may include a housing 304. In an embodiment, housing 304 may be a portion of housing 260 as described above. In another embodiment, housing 304 may be a separate housing configured to only house plasma reactor 216. In a non-limiting example, plasma reactor 216 may include a plurality of housings. For example, and without limitation, as illustrated in FIG. 2, housing 304 may be disposed within housing 260. At least a pair of electrodes 220a-b and reaction region 228 in between electrodes of at least a pair of electrodes 220a-b may be disposed within housing 304. In some cases, housing 304 may be injection molded using an injectable mold. As used in this disclosure, an “injectable mold” is a manufacturing tool for producing plastic parts. Manufacturing housing 304 may include using an injection molding process, wherein the injection molding process may involve a use of injectable mold configured to create specific shape and features of housing 304. In some embodiments, injectable mold may include two halves that are clamped together, with one or more cavities in between, wherein the cavities may define the shape of housing 304. In some cases, material such as, without limitation, molten plastic may be injected into the injectable mold under high pressure, filling the space and taking on the shape of injectable mold. Injection molding process may include a cooling process which is configured to cool and/or solidify injected material. Injectable mold may be then opened and finished housing 304 may be removed. In some embodiments, injectable mold may be precisely machined to desired shape and size of housing 304. In a non-limiting example, housing 304 may include a hollow cylinder.

With continued reference to FIG. 3, one or more continuous conductor 236a-b may pass through housing 304, with one end electrically connected to at least an electrode 308 of at least a pair of electrodes 220a-b. In some cases, at least an electrode 308 may include a first electrode 220a. In other cases, at least an electrode 308 may include second electrode 220b. Another end of continuous conductor 236a-b may be connected to ignition unit 232 or ground 224 as described above with reference to FIG. 2. In some embodiments, one or more insulators 312a-b may be used at the point where continuous conductor 236a-b passes through housing 304. An “insulator,” for the purpose of this disclosure, is a material that does not readily conduct heat, electricity, or sound. In a non-limiting example, insulators 312a-b may include electrical insulators, wherein the electrical insulators are material that have high electrical resistivity. Electrical insulators may not readily conduct electric current, thereby preventing the flow of electricity between plasma reactor 216 with other components except ignition unit 232, reducing the risk of short circuits, electrical shocks, interference, and the like. Exemplary electrical insulator may include plastics, ceramics, glass, rubber, and the like.

With continued reference to FIG. 3, each electrode of the at least a pair of electrodes 220a-b may include a pitch angle 316. In a non-limiting example, at least an electrode 308 may include a pitch angle 316 of 22 degrees. As used in this disclosure, a “pitch angle” of an electrode refers to an angle between the electrode's longitudinal axis and a reference plane or axis within plasma reactor 216. In some cases, pitch angle 316 may impact on characteristics of plasma generated between electrodes in reaction region 228 such as, without limitation, electric field distribution, efficiency of electrical discharge process, interaction with reactive species (e.g., ROS, RNS, and the like) within the plasma.

With continued reference to FIG. 3, injector 240 may be connected to plasma reactor 216 using an injector mount flange 320. As used in this disclosure, an “injector mount flange” is a mechanical component used to securely attach injector 240 to housing 304 in a reliable and leak-proof manner. In a non-limiting example, injector mount flange 320 may include an interface 324 between injector 240 and plasma reactor 216. In some cases, at least a fluid outlet 248 of injector 240 may include a threaded adaptor. Both at least a fluid outlet 248 and interface 324 may include a threaded section; for instance, and without limitation, at least a fluid outlet 248/interface 324 may include a male/female threaded section, wherein the male and the female threaded section are compatible (i.e., matched). Injector 240 may be threaded, using at least a fluid outlet 248 with threaded adaptor onto injector mount flange 320 at interface 324.

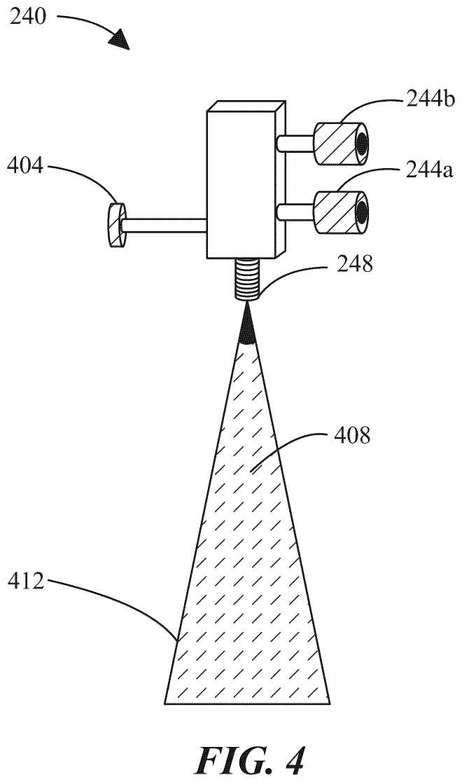

Now referring to FIG. 4, an exemplary embodiment of an injector 240 with a flow adjustment component 404 is illustrated. In some embodiments, injector 240 may include a plurality of fluid inlets 244a-b. In a non-limiting example, injector 240 may include a first fluid inlet 244a in fluidic connection with first reservoir, wherein the first fluid inlet may be configured to accept first fluid from first reservoir. First fluid may include one or more gases as described above. Injector 240 may include a second fluid inlet 244b in fluidic connection with second reservoir, wherein second fluid inlet 244b may be configured to accept second fluid from second reservoir. Second fluid may include liquid such as, without limitation, water. In some cases, at least a fluid outlet 248 may be configured to output a mixture of first fluid and second fluid in the form of droplets to plasma reactor. In some embodiments, injector 240 may include an atomizer. In a non-limiting example, injector 240 may produce droplets through different mechanisms, such as, without limitation, pressure-driven atomization, ultrasonic atomization, electrostatic atomization, and the like. Injector 240 may break second fluid down into small droplets which may then be dispersed and mixed with first fluid. In some cases, droplets may carry reactants into reaction region 228 of plasma reactor 216. In some cases, droplets may enhance the mixing and interaction between different fluids or reactive species within plasma reactor, thereby improving the efficiency and/or uniformity of the treatment process.

With continued reference to FIG. 4, as used in this disclosure, a “flow adjustment component” is a device that allows for the precise control and regulation of the fluid flow rate through the injector. In some cases, flow adjustment component 404 may include a manual flow control valve which can be adjusted by hand to regulate the fluid flow rate through injector 240. In a non-limiting example, by turning a knob, valve opening or the opening of at least a fluid outlet 248 may be changed, allowing for more or less fluid to pass through injector 240 or introduce into plasma reactor 216. Additionally, or alternatively, flow adjustment component 404 may include an 8× turn-down ratio. As used in this disclosure, a “turn-down ratio” is a measure of the versatility and flexibility of flow adjustment component 404 which indicates how well flow adjustment component 404 may accommodate different flow rate requirements within a system. Such flow adjustment component 404 may control fluid flow rate over a range of eight times the minimum flow rate. For example, if the minimum flow rate of flow adjustment component 404 is 2 gallon per minute (GPM), an 8× turn-down ratio may indicate that flow adjustment component 404 may be able to effectively regulate flow rates from 2 GPM up to 8 GPM. In a non-limiting example, at least a fluid outlet 248 of injector 240 may output gas 5˜8μ water drops 408 in a 22˜25 degrees spray cone 412. The spray cone 412 disclosed herein may be consistent with a cone shape of droplets disclosed with respect to FIG. 2.

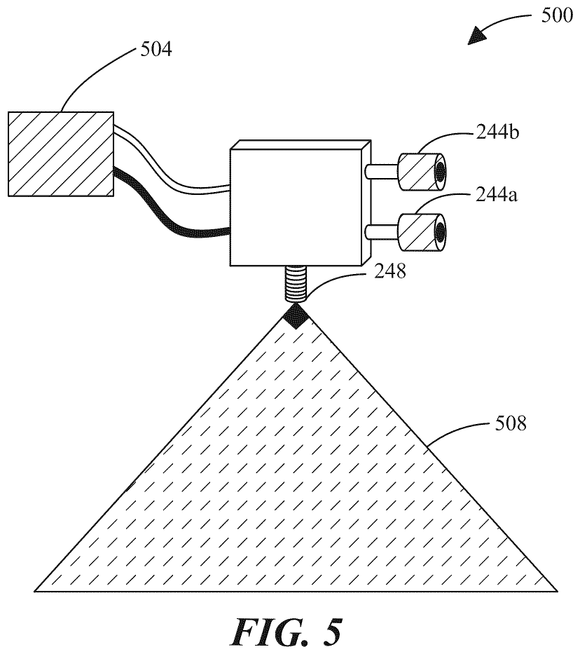

Now referring to FIG. 5, an exemplary embodiment of a piezo water vapor injector 500 is illustrated. As used in this disclosure, a “piezo water vapor injector” is a type of injector 240 that utilizes piezoelectric technology to generate water vapor by atomizing at least a liquid (i.e., second fluid) into fine droplets as described above. “Water vapor,” as described herein, is the gaseous phase of water (i.e., second fluid), which occurs when water molecules gain enough energy to break free from liquid state and become dispersed in surrounding air (i.e., first fluid). “Piezoelectric technology,” as described herein, is a technology based on a piezoelectric effect. The piezoelectric effect is a phenomenon where certain materials generate an electric charge when subjected to mechanical stress or the other way around (i.e., undergo mechanical deformation when exposed to electric field). In some cases, materials such as ceramics (e.g., lead zirconate titanate), quartz crystals, polymers, and the like may exhibit such an effect. Piezo water vapor injector 500 may include a piezoelectric element; for instance, and without limitation, a ceramic disk or plate may be used to create mechanical vibrations at certain frequencies when an electrical voltage is applied by power source 504. Power source 504 may include any power source as described above in this disclosure such as a DC power supply. Mechanical vibrations may be transmitted to at least a fluid input from at least a fluid inlet (i.e., first fluid inlet 244a and/or second fluid inlet 244b), thereby causing at least a fluid to break up into fine droplets of mist, which then evaporate to form water vapor. In a non-limiting example, at least a fluid outlet 248 of piezo water vapor injector 500 may output at least 90 degrees water vapor and air discharge cone.

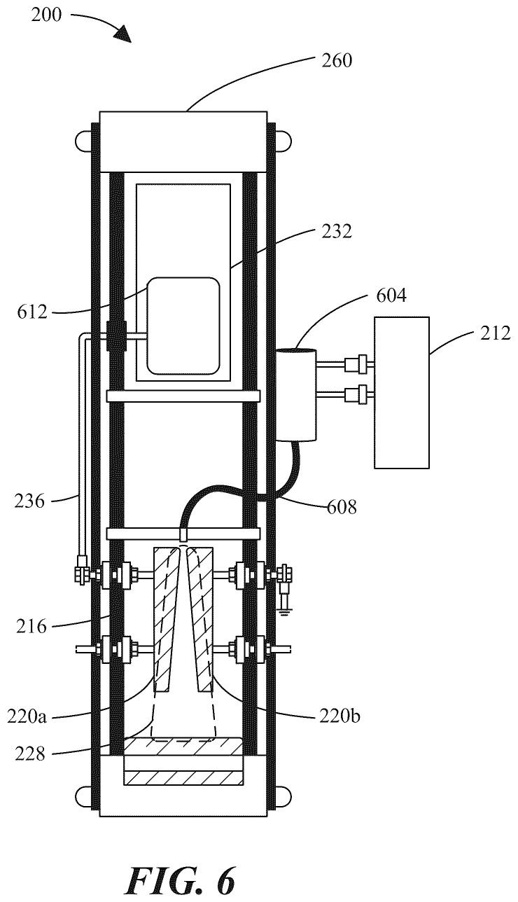

Now referring to FIG. 6, an exemplary embodiment of apparatus 100 for treating a growth medium using an electrical discharge with an external mounted injector 604 is illustrated. As used in this disclosure, an “external mounted injector” is an injector that is installed on the exterior of apparatus 100, rather than being integrated within apparatus 100 as described above with reference to FIGS. 1-5. External mounted injector 604 may include any injector as described above such as, without limitation, injector 140 (air & water injector), Piezo water vapor injector 400, and the like. In some embodiments, external mounted injector 604 may be designed to deliver at least a fluid from at least a reservoir 112 into plasma reactor 116 from an external location using a tube 608. In a non-limiting example, external mounted injector 604 may be mechanically fixed to the exterior of housing 160. In some cases, external mounted injector 604 may be attached to exterior of housing 160 using screw or bolt fastening, clamp or clip fastening, sliding or snap-fit connections, and/or the like.

Additionally, or alternatively, and still referring to FIG. 6, ignition unit 132 may include a coil 612. As used in this disclosure, a “coil” is a wound spiral or helix of conductive wire that creates an electromagnetic field when an electric current flows through it. In a non-limiting example, coil 612 may be electrically connected to at least an electrode (i.e., first electrode 120a) of at least a pair of electrodes 120a-b, configured to initiate electrical discharge in plasma reactor 116. Coil may include an induction coil or a high-voltage transformer coil, wherein the induction coil or the high-voltage transformer coil may generate high-voltage electrical pulses necessary to create electrical discharge between first electrode 120a and second electrode 120b.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

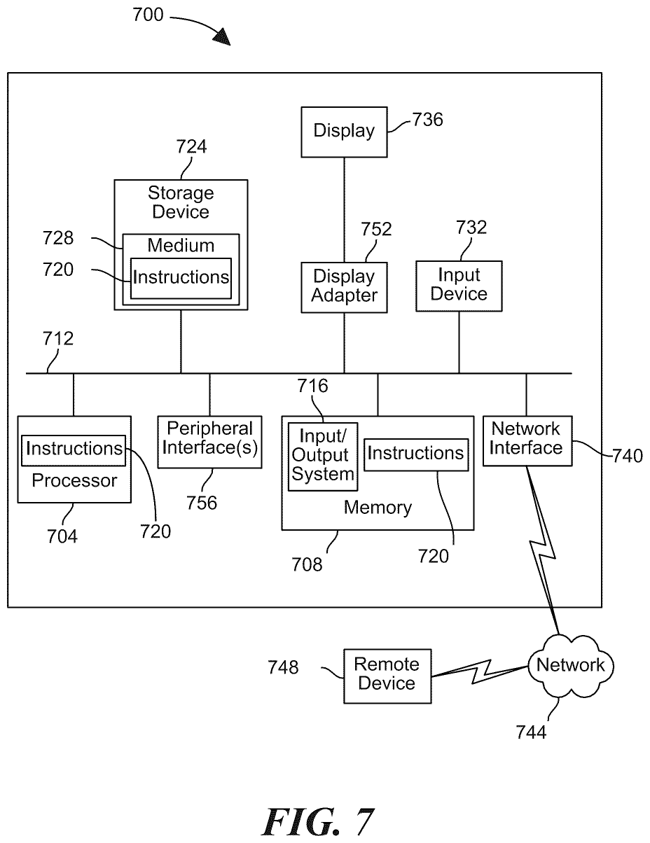

FIG. 7 shows a diagrammatic representation of one embodiment of a computing device in the exemplary form of a computer system 700 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 700 includes a processor 704 and a memory 708 that communicate with each other, and with other components, via a bus 712. Bus 712 may include any of several types of bus structures including, but not limited to, a memory bus, a memory controller, a peripheral bus, a local bus, and any combinations thereof, using any of a variety of bus architectures.

Processor 704 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 704 may be organized according to Von Neumann and/or Harvard architecture as a non-limiting example. Processor 704 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC).

Memory 708 may include various components (e.g., machine-readable media) including, but not limited to, a random-access memory component, a read only component, and any combinations thereof. In one example, a basic input/output system 716 (BIOS), including basic routines that help to transfer information between elements within computer system 700, such as during start-up, may be stored in memory 708. Memory 708 may also include (e.g., stored on one or more machine-readable media) instructions (e.g., software) 720 embodying any one or more of the aspects and/or methodologies of the present disclosure. In another example, memory 708 may further include any number of program modules including, but not limited to, an operating system, one or more application programs, other program modules, program data, and any combinations thereof.

Computer system 700 may also include a storage device 724. Examples of a storage device (e.g., storage device 724) include, but are not limited to, a hard disk drive, a magnetic disk drive, an optical disc drive in combination with an optical medium, a solid-state memory device, and any combinations thereof. Storage device 724 may be connected to bus 712 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 724 (or one or more components thereof) may be removably interfaced with computer system 700 (e.g., via an external port connector (not shown)). Particularly, storage device 724 and an associated machine-readable medium 728 may provide nonvolatile and/or volatile storage of machine-readable instructions, data structures, program modules, and/or other data for computer system 700. In one example, software 720 may reside, completely or partially, within machine-readable medium 728. In another example, software 720 may reside, completely or partially, within processor 704

Computer system 700 may also include an input device 732. In one example, a user of computer system 700 may enter commands and/or other information into computer system 700 via input device 732. Examples of an input device 732 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 732 may be interfaced to bus 712 via any of a variety of interfaces (not shown) including, but not limited to, a serial interface, a parallel interface, a game port, a USB interface, a FIREWIRE interface, a direct interface to bus 712, and any combinations thereof. Input device 732 may include a touch screen interface that may be a part of or separate from display 736, discussed further below. Input device 732 may be utilized as a user selection device for selecting one or more graphical representations in a graphical interface as described above.

A user may also input commands and/or other information to computer system 700 via storage device 724 (e.g., a removable disk drive, a flash drive, etc.) and/or network interface device 740. A network interface device, such as network interface device 740, may be utilized for connecting computer system 700 to one or more of a variety of networks, such as network 744, and one or more remote devices 748 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 744, may employ a wired and/or a wireless mode of communication. In general, any network topology may be used. Information (e.g., data, software 720, etc.) may be communicated to and/or from computer system 700 via network interface device 740.

Computer system 700 may further include a video display adapter 752 for communicating a displayable image to a display device, such as display device 736. Examples of a display device include, but are not limited to, a liquid crystal display (LCD), a cathode ray tube (CRT), a plasma display, a light emitting diode (LED) display, and any combinations thereof. Display adapter 752 and display device 736 may be utilized in combination with processor 704 to provide graphical representations of aspects of the present disclosure. In addition to a display device, computer system 700 may include one or more other peripheral output devices including, but not limited to, an audio speaker, a printer, and any combinations thereof. Such peripheral output devices may be connected to bus 712 via a peripheral interface 756. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions, and additions may be made to that which is specifically disclosed herein without departing from the spirit and scope of the present invention.

What is claimed is:

1. An apparatus for improved injection for a plasma reactor, wherein the apparatus comprises: at least:
a reservoir;
a plasma reactor;
an ignition unit;
and an injector,
wherein:
the plasma reactor comprises at least a pair of electrodes comprising a first electrode and a second electrode, wherein the at least a pair of electrodes is configured to produce an electrical discharge; and wherein
the injector is configured to feed at least a fluid from the at least a reservoir through reaction region of the plasma reactor; and
the injector comprises at least a fluid outlet, wherein:
the at least a fluid outlet is configured to output the at least a fluid in a cone distribution to the plasma reactor, wherein the cone distribution comprises:
a distribution angle; and
droplets of the at least a
fluid.

2. The apparatus of claim 1, wherein the at least a reservoir comprises: a first reservoir configured to contain a first fluid; and
a second reservoir configured to contain a second fluid,
wherein: the first fluid comprises at least a gas; and
the second fluid comprises at least a liquid.

3. The apparatus of claim 2, wherein the injector further comprises:
a first fluid inlet in fluidic connection with the first reservoir, wherein the first fluid inlet is configured to accept the first fluid from the first reservoir; and
a second fluid inlet in fluidic connection with the second reservoir, wherein the second fluid inlet is configured to accept the second fluid from the second reservoir.

4. The apparatus of claim 3, wherein the at least a fluid outlet is further configured to output a mixture of the first fluid and the second fluid in the cone distribution of the at least a fluid to the plasma reactor.

5. (canceled)

6. The apparatus of claim 1, wherein:
each of the at least a pair of electrodes comprises a pitch angle of 12 degrees; and the distribution angle of the cone distribution comprises 12 degrees.

7. The apparatus of claim 6, wherein the first electrode of the at least a pair of electrodes and the second electrode of the at least a pair of electrodes comprise different shapes.

8. The apparatus of claim 7, wherein the plasma reactor comprises a reaction region disposed between the first electrode and the second electrode, wherein the reaction region is configured to enable an interaction between the electrical discharge and a growth medium.

9. The apparatus of claim 8, further comprising a treatment chamber, wherein the treatment chamber is configured to contain the growth medium.

10. The apparatus of claim 8, wherein the reaction region comprises a plurality of points on an arc between the first electrode of the at least a pair of electrodes and the second electrode of the at least a pair of electrodes.

11. The apparatus of claim 1, wherein the droplets of the at least a fluid of the cone distribution comprises microfine droplets.

12. The apparatus of claim 11, wherein the microfine droplets comprises a diameter of 5μ.

13. The apparatus of claim 1, wherein the at least a fluid outlet of the injector comprises a nozzle.

14. The apparatus of claim 1, wherein the injector is mounted externally to the plasma reactor.

15. The apparatus of claim 1, wherein the injector comprises a flow adjustment component configured to regulate a flow of the at least a fluid entering the reaction region.

16. The apparatus of claim 1, wherein the injector comprises one or more valves, wherein the one or more valves are configured to control the flow of the at least a fluid fed through the reaction region of the plasma reactor.

17. The apparatus of claim 1, wherein the injector comprises a piezo water vapor injector.

18. The apparatus of claim 1, wherein the cone distribution of the at least a fluid is further configured to produce a nitrogen oxide concentration.

19. The apparatus of claim 1, further comprising a pressure regulator, wherein the pressure regulator is configured to transfer the at least a fluid to the injector.

20. The apparatus of claim 19, wherein the pressure regulator is further configured to pressurize the at least a fluid entering the reaction region.
